(19) United States
(12) Patent Application Publication
(10) Pub. No.: US 2018/0182600 A1
(43) Pub. Date: Jun. 28, 2018

(54) PLASMA SYSTEM AND METHOD OF FABRICATING A SEMICONDUCTOR DEVICE USING THE SAME

(71) Applicant: Samsung Electronics Co., Ltd., Suwon-si (KR)

(72) Inventors: MinKyu SOHN, Suwon-si (KR); DOUGYONG SUNG, Seoul (KR); SeungBo SHIM, Seoul (KR); JaeWon JEONG, Hwaseong-si (KR); PETER BYUNGHOON HAN, Suwon-si (KR)

(21) Appl. No.: 15/826,665

(22) Filed: Nov. 29, 2017

(30) Foreign Application Priority Data
Dec. 28, 2016 (KR) 10-2016-0181309

(51) Int. Cl. H01J 37/32; H01L 21/67

(52) U.S. Cl. CPC H01J 37/32146; H01L 21/67069; H01J 2237/3347; H01J 37/32972; H01J 2237/327; H01L 21/67253

(57) ABSTRACT

A plasma system includes an electrode and an RF power supply unit supplying an RF power to the electrode to generate a plasma on the electrode. The RF power is provided in a pulse having a valley-shaped portion during an on-pulsing interval of the pulse. The valley-shaped portion is defined by a valley angle and a valley width. By controlling the valley angle and the valley width, the plasma may control the etching of a substrate.

### CROSS-REFERENCE TO RELATED APPLICATION

This application claims priority under 35 U.S.C. § 119 to Korean Patent Application No. 10-2016-0181309, filed on Dec. 28, 2016, in the Korean Intellectual Property Office, the disclosure of which is incorporated by reference herein in its entirety.

### TECHNICAL FIELD

The present inventive concept relates to a plasma system, and a method of fabricating a semiconductor device using the same.

### DISCUSSION OF RELATED ART

Semiconductor devices are manufactured using a plurality of unit processes, such as a deposition process, a diffusion process, a thermal process, a photo-lithography process, a polishing process, an etching process, an ion implantation process, and a cleaning process. Here, the etching process is classified into dry and wet etching processes. The dry etching process is performed using a chemically reactive plasma. The plasma provides high-energy ions to the wafer surface to etch or pattern a wafer. Depending on the energy distribution or incoming flux of the ions from the plasma, the etch profile (or etch selectivity) of the wafer may be controlled.

### SUMMARY

According to an exemplary embodiment of the present inventive concept, a plasma system includes an electrode and an RF power supply unit supplying an RF power to the electrode to generate a plasma on the electrode. The RF power is provided in a pulse having a valley-shaped portion during an on-pulsing interval of the pulse. The valley-shaped portion is defined by a valley angle and a valley width.

According to an exemplary embodiment of the present inventive concept, the RF power supply unit changes an absolute value of the valley angle. The energy of ions of the plasma incident on the electrode is proportional to the absolute value of the valley angle.

According to an exemplary embodiment of the present inventive concept, the RF power supply unit changes the valley width. The energy of ions of the plasma incident on the electrode is inversely proportional to the valley width.

According to an exemplary embodiment of the present inventive concept, the RF power supply unit controls at least one of the valley angle and the valley width of the RF power to adjust an incoming flux of ions of the plasma incident on the electrode.

According to an exemplary embodiment of the present inventive concept, the RF power supply unit controls an intermediate RF energy level of the valley-shaped portion to change the energy of the ions of the plasma.

According to an exemplary embodiment of the present inventive concept, the RF power supply unit produces a pulse of which an envelope is of a letter ‘M’-like shape.

According to an exemplary embodiment of the present inventive concept, the RF power supply unit produces a pulse of which an envelope is a letter ‘M’-like shape having a curved hill.

According to an exemplary embodiment of the present inventive concept, the RF power supply unit produces a pulse of which an envelope is of a letter ‘U’-like shape.

According to an exemplary embodiment of the present inventive concept, the pulse has a single valley-shaped waveform during the on-pulsing interval.

According to an exemplary embodiment of the present inventive concept, the plasma system further includes a detector measuring optical characteristics of light emitted from the plasma. The RF power supply unit includes an RF power generator, an impedance matching circuit provided between the RF power generator and the electrode, and an RF power controller provided between and connected to the RF power generator and the detector. The RF power controller controls the RF power generator so that the RF power has a pulse with a controlled valley angle and valley width.

According to an exemplary embodiment of the present inventive concept, a method of fabricating a semiconductor device is provided as follows. A substrate is prepared. Plasma is generated using an RF power provided in a pulse. The substrate is etched using the plasma. The pulse has a valley-shaped portion during an on-pulsing interval of the pulse. The valley-shaped portion is defined by a valley angle and a valley width. The plasma generation includes controlling at least one of a valley angle and a valley width to control the energy of ions of the plasma that are incident on the substrate.

According to an exemplary embodiment of the present inventive concept, the etching of the substrate includes forming a trench in the substrate using the RF power having a first valley angle of the pulse, while a polymer is deposited in a sidewall of the trench of the substrate, adjusting of the RF power to a second valley angle different from the first valley angle of the pulse, and etching the deposited polymer layer and a bottom surface of the trench of the substrate using the RF power having the second valley angle.

According to an exemplary embodiment of the present inventive concept, the second valley angle is greater than the first valley angle.

According to an exemplary embodiment of the present inventive concept, the etching of the substrate includes forming a trench in the substrate using the RF power having a first valley width of the pulse while a polymer is deposited on a sidewall of the trench of the substrate, adjusting the RF power to a second valley width different from the first valley width of the pulse, and etching the deposited polymer layer and a bottom surface of the trench of the substrate using the RF power having the second valley width.

According to an exemplary embodiment of the present inventive concept, the second valley width is smaller than the first valley width. According to an exemplary embodiment of the present inventive concept, a method of fabricating a semiconductor device is provided as follows. A substrate is provided. A first RF power having a plurality of first pulses is generated. Each of the plurality of first pulses has a first valley-shaped envelope. A first etching process is performed on the substrate using the first RF power to form a trench having a first depth while a polymer is deposited on a sidewall of the trench. A second RF power having a plurality of second pulses is generated. Each of the plurality of second pulses has a second valley-shaped envelop. A second etching process is performed on the substrate using the second RF power so that a bottom of the trench is etched down to a second depth and the polymer on the sidewall of the trench is removed. The first valley-shaped envelope is defined by a first valley angle and a first valley width. The second valley-shaped envelop is defined by a second valley angle and a second valley width. The polymer is generated from the substrate during the first etching process.

According to an exemplary embodiment of the present inventive concept, each of the plurality of first pulses has a first maximum RF power level, a first minimum RF power level, and a first intermediate RF power level. Each of the plurality of first pulses includes a first rising edge extending from the first minimum RF power level to the first maximum RF power level, a first falling edge extending from the first maximum RF power level to the first minimum RF power level, a first left-valley hill extending from the first maximum RF power level to the first intermediate RF power level and a first right-valley hill extending from the first intermediate RF power level to the first maximum RF power level.

According to an exemplary embodiment of the present inventive concept, each of the plurality of second pulses has a second maximum RF power level, a second minimum RF power level, and a second intermediate RF power level. Each of the plurality of second pulses has a second rising edge extending from the second minimum RF power level to the second maximum RF power level, a second falling edge extending from the second maximum RF power level to the second minimum RF power level, a second left-valley hill extending from the second maximum RF power level to the second intermediate RF power level and a second right-valley hill extending from the second intermediate RF power level to the second maximum RF power level.

According to an exemplary embodiment of the present inventive concept, each of the plurality of first pulses further includes a first valley bottom connecting the first left-valley hill and the first right-valley hill at the first intermediate RF power level.

According to an exemplary embodiment of the present inventive concept, the first right-valley hill is sloped at a first valley angle, and the second right-valley hill is sloped at a second valley angle greater than the first valley angle.

### BRIEF DESCRIPTION OF THE DRAWINGS

These and other features of the present inventive concept will become more apparent by describing in detail exemplary embodiments thereof with reference to the accompanying drawings of which:

FIG. 1 is a schematic diagram illustrating a plasma system according to an exemplary embodiment of the present inventive concept;

FIG. 2 is a diagram showing an example of radio-frequency (RF) power of FIG. 1 according to an exemplary embodiment of the present inventive concept;

FIG. 3 is a diagram illustrating a wave form of a pulse to be generated during an on-pulsing interval of FIG. 2 according to an exemplary embodiment of the present inventive concept;

FIG. 4 is a diagram illustrating an example of a pulse to be generated during an on-pulsing interval of FIG. 2 according to an exemplary embodiment of the present inventive concept;

FIG. 5 is a diagram illustrating another example of a pulse to be generated during an on-pulsing interval of FIG. 2 according to an exemplary embodiment of the present inventive concept;

FIG. 6 is a diagram illustrating an example of a pulse, which has a second valley angle different from a first valley angle of FIG. 3 according to an exemplary embodiment of the present inventive concept;

FIGS. 7 and 8 are sectional views illustrating a substrate, on which an etching process using the plasma of FIG. 1 has been performed, according to an exemplary embodiment of the present inventive concept;

FIG. 9 is a graph showing a change in ion flux caused by a change in ion energy of plasma according to an exemplary embodiment of the present inventive concept;

FIG. 10 is a diagram showing a pulse, in which a valley has a valley width smaller than a valley width of FIG. 3 according to an exemplary embodiment of the present inventive concept;

FIG. 11 is a diagram showing a pulse, in which a valley has a height greater than a height of FIG. 3 according to an exemplary embodiment of the present inventive concept;

FIG. 12 is a flow chart illustrating a method of fabricating a semiconductor device using RF power of FIG. 1 according to an exemplary embodiment of the present inventive concept;

FIG. 13 is a sectional view illustrating trenches, which are respectively formed using two different pulses, according to an exemplary embodiment of the present inventive concept; and

FIG. 14 is a flow chart illustrating a method of fabricating a semiconductor device using RF power of FIG. 1 according to an exemplary embodiment of the present inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present. Like reference numerals may refer to the like elements throughout the specification and drawings.

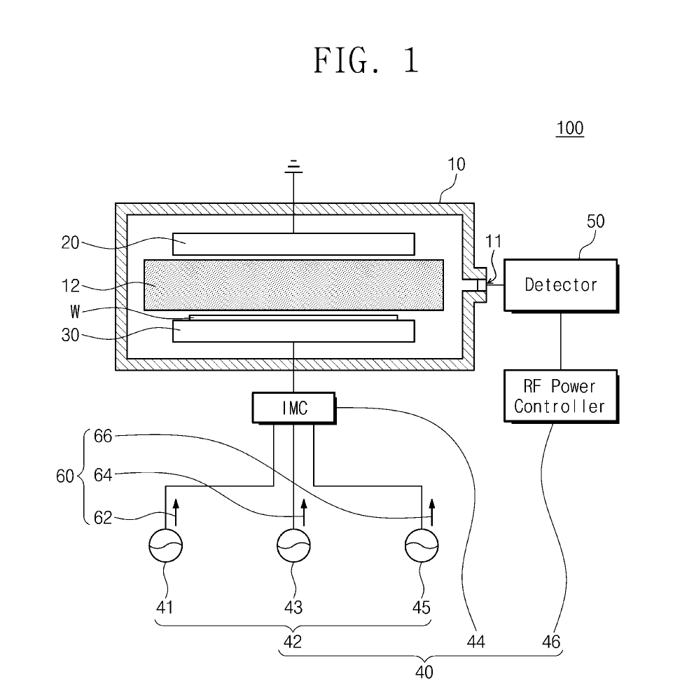

FIG. 1 is a schematic diagram illustrating a plasma system 100 according to an exemplary embodiment of the present inventive concept.

Referring to FIG. 1, the plasma system 100 may be or include a capacitively coupled plasma system. In an exemplary embodiment, the plasma system 100 may be an inductively coupled plasma system or a microwave plasma system. For example, the plasma system 100 may include a chamber 10, an upper electrode 20, a lower electrode 30, a radio frequency (RF) power supply unit 40, and a detector 50.

The chamber 10 may be configured to contain a substrate W. The chamber 10 may provide an isolated space, in which a fabrication process is performed on the substrate W. The substrate W may be loaded on an electrostatic chuck (not shown), which is provided in a lower region of the chamber 10. The electrostatic chuck may be configured to hold the substrate W using an electrostatic voltage.

The upper electrode 20 may be provided in an upper region of the chamber 10. For example, the upper electrode 20 may be connected to a ground voltage.

The lower electrode 30 may be provided in the lower region of the chamber 10 to face the upper electrode 20. The lower electrode 30 may be provided in the electrostatic chuck. The substrate W may be loaded on the lower electrode 30, during the fabrication process. If an RF power 60 is applied to the lower electrode 30, plasma 12 may be produced on the substrate W. For example, the RF power 60 may be used to produce the plasma 12 from a reaction gas in the chamber 10. A reaction gas supply unit (not shown) may be provided to supply the reaction gas into the chamber 10. In an exemplary embodiment, the plasma 12 may be used to etch the substrate W.

The RF power supply unit 40 may be connected to the lower electrode 30. The RF power supply unit 40 may be configured to supply the RF power 60 to the lower electrode 30. In an exemplary embodiment, the RF power supply unit 40 may include an RF power generator 42, an impedance matching circuit (IMC) 44, and a RF power controller 46.

The RF power generator 42 may be used to generate the RF power 60. In an exemplary embodiment, the RF power generator 42 may include first to third RF power sources 41, 43, and 45. The first to third RF power sources 41, 43, and 45 may be configured to generate first to third RF powers 62, 64, and 66, respectively. In an exemplary embodiment, the first RF power 62 may serve as a source RF power of the plasma 12. The first RF power 62 may have a frequency of about 60 MHz. The second RF power 64 may serve as a stabilization RF power. The second RF power 64 may be used to stabilize the first and third RF powers 62 and 66. The second RF power 64 may have a frequency of about 9.8 MHz. The third RF power 66 may serve as a bias RF power. The third RF power 66 may be used to concentrate the plasma 12 on the substrate W. The third RF power 66 may have a frequency ranging from about 100 KHz to about 2 MHz.

The impedance matching circuit 44 may be provided between and connected to the first to third RF power sources 41, 43, and 45 and the lower electrode 30. The impedance matching circuit 44 may be configured to control the first to third RF powers 62, 64, and 66, for impedance matching between the plasma 12 and the first to third RF power sources 41, 43 and 45. In an exemplary embodiment, the impedance matching circuit 44 may be in plural so that each impedance matching circuit is coupled to one of the RF power sources 41, 43 and 45.

The RF power controller 46 may be provided between and connected to the impedance matching circuit 44 and the detector 50. In an exemplary embodiment, the RF power controller 46 may be connected to the first to third RF power sources 41, 43, and 45. In this case, the first to third RF powers 62, 64, and 66 may be controlled by the RF power controller 46.

The detector 50 may be provided near a viewport 11 of the chamber 10. For example, the detector 50 may be positioned near the viewport 11 to the extent that the detector 50 receives light, through the viewport 11, generated in the chamber 10. In an exemplary embodiment, the detector 50 may be or include an optical sensor, such as a charge-coupled device (CCD) image sensor device and a complementary-metal-oxide-semiconductor (CMOS) image sensor device. The detector 50 may be used to measure wavelength and intensity of light, which is emitted from the plasma 12 through the viewport 11. Data measured by the detector 50 may be transmitted to the RF power controller 46 and may be used to control the first to third RF powers 62, 64, and 66.

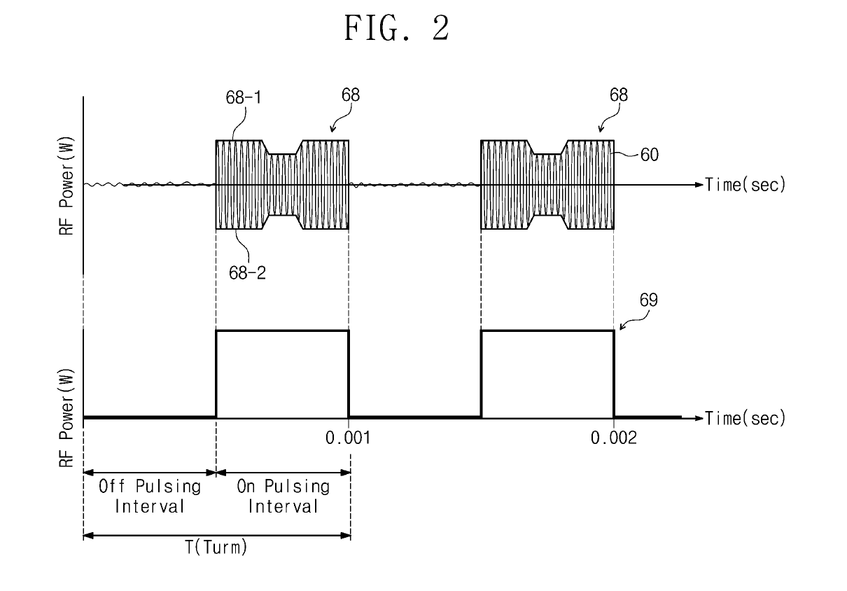

FIG. 2 illustrates the RF power 60 of FIG. 1 according to an exemplary embodiment of the present inventive concept.

Referring to FIG. 2, the RF power 60 may be provided in the form of pulse trains.

For example, the RF power 60 may be generated to have a plurality of pulses 68 in its waveform. The shape of each of the plurality of pulses 68 may be determined by the first to third RF powers 62, 64, and 66 of the RF power 60. For example, each of the plurality of pulses 68 may include an upper envelope 68-1 and a lower envelope 68-2 which determines the shape of each of the plurality of pulses.

In an exemplary embodiment, the shape of the pulse 68 may be changed by adjusting peak levels (or amplitude) of the first to third RF powers 62, 64, and 66. In this case, the RF power controller 46 may control a peak level of each of the first to third RF power sources 41, 43 and 45 such that the shape of the pulse 68 is generated.

In an exemplary embodiment, a phase of each of the first to third RF powers 62, 64 and 66 may be controlled by the RF power controller 46. In this case, the RF power controller 46 may control the phase of each of the first to third RF power sources 41, 43 and 45 such that the shape of the pulse 68 is generated.

In an exemplary embodiment, a frequency of each of the first to third RF powers 62, 64 and 66 may be controlled by the RF power controller 46. In this case, the RF power controller 46 may control the frequency of each of the first to third RF power sources 41, 43 and 45 such that the shape of the pulse 68 is generated.

In an exemplary embodiment, the RF power controller 46 may control at least one of the peak level, the frequency and the phase of each of the first to third RF power sources 41, 43 and 45. In this case, the RF power controller 46 may control at least of the phase, the frequency and the peak level of each of the first to third RF power sources 41, 43 and 45 such that the shape of the pulse 68 is generated.

A frequency of the pulse 68 may be lower than a frequency of the third RF power 66. The pulse 68 may have a frequency of, for example, about 100 Hz to about 10 KHz. In FIG. 2, the pulse 68 has a frequency of about 1 KHz. The pulse 68 has a period of about 0.001 second. The pulse trains may include an on-pulsing interval and an off-pulsing interval in the period of the pulse trains. For example, the pulse 68 may exist in the on-pulsing interval, and the shape of the pulse 68 may be defined by the upper envelope 68-1 and the lower envelope 68-2 within the on-pulsing interval. The on-pulsing interval and the off-pulsing interval may have the same time length. For example, the on-pulsing interval and the off-pulsing interval may have a time length of about 0.0005 second. The present inventive concept is not limited thereto. For example, the time length of the on-pulsing interval may be different from the time length of the off-pulsing interval. The shape of the pulse 68 may be different from a shape of a pulse 69 having a typical rectangular waveform. For example, the upper envelope 68-1 and the lower envelope 68-2 of the pulse 68 may be valley-shaped unlike the rectangular waveform (lower one in FIG. 2) having a flat envelope in the on-pulsing interval.

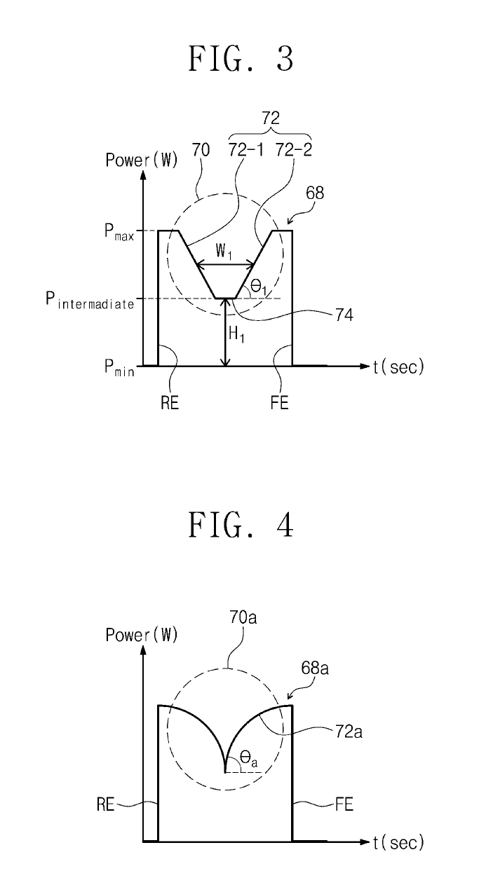

FIG. 3 illustrates a waveform of the pulse 68 within the on-pulsing interval of FIG. 2 according to an exemplary embodiment of the present inventive concept. Specifically, FIG. 3 shows an upper envelope of the pulse according to an exemplary embodiment of the present inventive concept. The lower envelop of the pulse may have a mirror-symmetric shape regarding the upper envelop.

Referring to FIG. 3, the pulse 68 may be shaped like a letter ‘M’ during an on-pulsing interval. In an exemplary embodiment, the pulse 68 may be shaped like a slanted or distorted letter M. The RF power controller 46 may be configured to allow the pulse 68 to have the M-shaped waveform. For example, the RF power controller 46 may control at least one of the peak level, the frequency and the phase of each of the first to third RF power sources 41, 43 and 45 such that the envelope of the pulse 68 may have the M-shaped waveform. The envelope of the pulse 68 having the M-shaped waveform may have a valley-shaped portion (hereinafter, a valley 70).

In an exemplary embodiment, the pulse 68 may have a single valley 70, within an interval from a rising edge RE to a falling edge FE. The envelop of the pulse 68 may have oblique lines 72 and a bottom line 74 defining the valley 70. The oblique lines 72 may be located between the rising edge RE and the falling edge FE, and the bottom line 74 may be located between the oblique lines 72.

The oblique lines 72 may include a first oblique line 72-1 and a second oblique line 72-2 opposite and symmetric to each other regarding the bottom line 74. The first oblique line 72-1 may be referred to as a left-valley hill, and the second oblique line 72-2 may be referred to a right-valley hill. In an exemplary embodiment, the waveform of the RF power 60 may be controlled so that the oblique lines 72 each have a first valley angle θ₁ and the oblique lines 72 are spaced apart from each other at a first valley width W₁.

The first valley angle I may be an angle of each of the oblique lines 72 of the valley 70, relative to a base (e.g., x-axis) of time. In an exemplary embodiment, the first valley angle I may be about ±45° or about ±30°.

The first valley width W₁ may be given by a length of time between the oblique lines 72. The first valley width W₁ may change between the rising edge RE and the falling edge FE. For example, the first valley width W₁ may be a temporal distance between the oblique lines 72, measured at a first or second power level. Here, the first RF power level may be selected as a middle level between RF powers at the rising edge RE (its maximum RF power level) and the bottom line 74, and the second RF power level may be selected as a middle level between RF powers at the falling edge FE (its maximum RF power level) and the bottom line 74.

For the convenience of description, the pulse 68 may have a maximum RF power level Pₘₐₓ, a minimum RF power level Pₘᵢₙ and an intermediate RF power level P_{intermediate}. In this case, the first valley width W₁ may be a temporal distance between the left-valley hill 72-1 and the right-valley hill 72-2 at a predetermined RF power level. The predetermined RF power level may be a middle RF power level between the maximum RF power level Pₘₐₓ and the intermediate RF power level P_{intermediate} of the bottom line 74. In this case, the bottom line 74 may be referred to as a valley bottom. The RF power level of the bottom line 74 (the valley bottom) may be the intermediate RF power level P_{intermediate}. The first valley width W₁ may range from about 0.0002 seconds to about 0.0003 seconds.

The intermediate RF power level of the pulse 68 at the bottom line 74 may be higher than a base power (the minimum RF power level Pₘᵢₙ) and may be lower than the power level at the rising and falling edges RE and FE. For example, the intermediate RF power level P_{intermediate} of the bottom line 74 may be an RF power level between the maximum RF power level Pₘₐₓ and the minimum RF power level Pₘᵢₙ of the pulses 68. A first height H₁ in FIG. 3 may represent the intermediate RF power level P_{intermediate} of the pulse 68 at the bottom line 74 and may be measured as the difference from the base power (the minimum RF power level Pₘᵢₙ). In an exemplary embodiment, the first height H₁ may be half the difference from the base power Pₘᵢₙ and the maximum RF power level Pₘₐₓ of the rising edge RE. In an exemplary embodiment, the bottom line (valley bottom) 74 may have a temporal length of about 0.0001 seconds.

FIG. 4 is a diagram illustrating a wave form of a pulse to be generated during the on-pulsing interval of FIG. 2 according to an exemplary embodiment of the present inventive concept.

Referring to FIG. 4, a pulse 68a shaped like a letter ‘M’ having a curved valley hill 72a may be generated. The pulse 68a may be generated in such a way that a valley angle θₐ of oblique lines 72a of a valley 70a gradually changes along the time axis (e.g., the x-axis). For example, the absolute value of the valley angle θₐ may gradually increase within an interval from the rising edge RE to a bottom of the valley 70a and may gradually decrease within an interval from the bottom of the valley 70a to the falling edge FE. The pulse 68a may generate no bottom line in the valley 70a. In an exemplary embodiment, the pulse 68a may generate a bottom line between the rising and falling edges RE and FE of the pulse 68a.

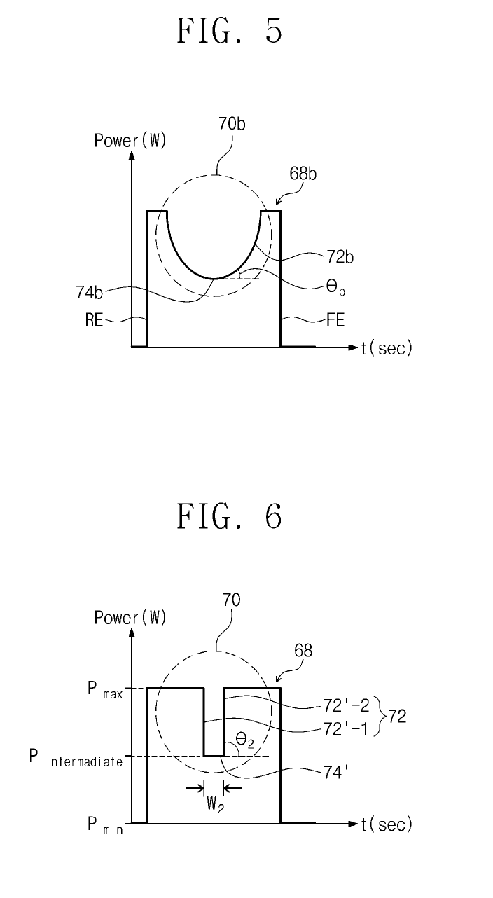

FIG. 5 is a diagram illustrating a wave form of a pulse to be generated during the on-pulsing interval of FIG. 2 according to an exemplary embodiment.

Referring to FIG. 5, a pulse 68b shaped like a letter ‘U’ may be generated. A valley angle θ_{b} of oblique lines 72b of a valley 70b of the pulse 68b may gradually decrease within an interval from the rising edge RE to a bottom of the valley 74b and may gradually increase within an interval from the bottom of the valley 74b to the falling edge FE. In this case, the bottom of the valley 74b may be the lowest point of the oblique lines 72b.

FIG. 6 illustrates an example of the pulse 68, which has a second valley angle θ₂ different from the first valley angle θ₁ of FIG. 3 according to an exemplary embodiment.

Referring to FIG. 6, the pulse 68 may be generated to allow the oblique lines 72 of the valley 70 to have a second valley angle θ₂. When measured and plotted under the same condition, the second valley angle θ₂ may be greater than the first valley angle θ₁ of FIG. 3. For example, when plotted in the same manner as that of FIG. 3, the second valley angle θ₂ may be about 90°. In this case, the oblique lines 72 may include a left-valley hill 72′-1 and a right-valley hill 72′-2; and a valley bottom 74 may connect the left-valley hill 72′1 and the right-valley hill 72′-2 at an intermediate RF power level P′_{intermediate}. The RF power 60 may be modulated to realize such a change in a valley angle of the oblique lines 72. In an exemplary embodiment, the second valley angle θ₂ may be about 60°. A change in a valley angle of the oblique lines 72 of the pulse 68 may lead to a change in etch rate of an etching process. For example, in the case where the etching process is performed on the substrate W, an etch rate of the substrate W may change depending on the change of the valley angle of the oblique lines 72 of the valley 70 from the pulse 68 (the first valley angle θ₁) of FIG. 3 to the pulse 68 (the second valley angle θ₂) of FIG. 6. In an exemplary embodiment, the etch rate of the substrate W may change depending on the change the valley width between the oblique lines 72 of the valley 70 from the pulse 68 (the first valley width WO of FIG. 3 to the pulse 68 (the second valley width W₂) of FIG. 6. In an exemplary embodiment, the etch rate of the substrate W may change depending on the change in at least one of the valley angle and the valley width.

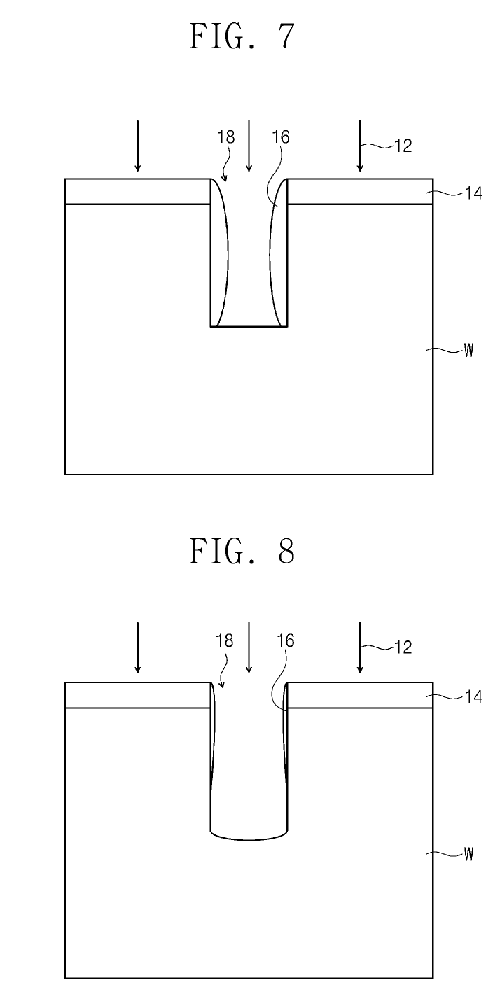

Each of FIGS. 7 and 8 illustrate cross-sectional views of the substrate W, on which an etching process using the plasma 12 of FIG. 1 has been performed, according to an exemplary embodiment of the present inventive concept.

Referring to FIGS. 3 and 7, in the case where the oblique lines 72 of the valley 70 have the first valley angle θ₁, a polymer 16 may be deposited in a trench 18 of the substrate W. The polymer 16 may be a byproduct generated from the substrate W in the etching process of the substrate W. The trench 18 may be defined by a mask pattern 14 on the substrate W. The mask pattern 14 may be formed of or include a photoresist layer or a hard mask layer (e.g., including silicon oxide). The polymer 16 may be deposited on the mask pattern 14. In an exemplary embodiment, a deposition amount of the polymer 16 in trench 18 may be inversely proportional to an absolute value of a valley angle of the oblique lines 72 of the valley 70 of the pulse 68. For example, as the first valley angle θ₁ decreases, a deposition rate of the polymer 16 increases and etch rates of the polymer 16 and the substrate W may be decreased. For example, as the first valley angle θ₁ increases, a deposition rate of the polymer 16 decreases.

Referring to FIGS. 6 and 8, the absolute value of the valley angle of the oblique lines 72 may be proportional to etch rates of the substrate W, the polymer 16, or both. In the case where the valley angle of the oblique lines 72 of the valley 70 is increased from the first valley angle θ₁ (of FIG. 3, for example) to the second angle θ₂ (of FIG. 6, for example), the etch rate of the substrate W may be increased. For example, a part of the substrate W and a portion of the polymer 16 in the trench 18 may be etched, when an etching process is performed on the resulting structure of FIG. 7 using the RF power 60 having the pulse shape of FIG. 6. In this case, the second valley angle θ₂ (of FIG. 6, for example) may be greater than a critical valley angle in which the etching rate of the polymer is substantially the same with the deposition rate of the polymer so that no change in polymer 16 occurs, when an etching process is performed on the resulting structure of FIG. 7 using an RF power having the critical valley angle. At the first valley angle θ₁ smaller than the critical valley angle, the polymer 16 continues to grow; and at the second valley angle θ₂ greater than the critical valley angle, the polymer layer 18 is removed. At the second valley angle θ₂, the polymer 16 deposited on the sidewall of the trench 18 may be removed in a faster rate than a deposition rate at which newly-generated polymers are deposited on the polymer 16. Accordingly, the polymer 16 of FIGS. 7 and 8 is removed when the etching process is performed on the resulting structure of FIG. 6 using the RF power having the pulse shape of FIG. 6. Thus, a deposition of the polymer 16 may be removed, and a depth of the trench 18 may be increased.

In the case where the second valley angle of the oblique lines 72 is decreased from θ₂ to the first valley angle θ₁, the etch rate of the substrate W, the polymer 16 or both may be decreased.

Referring back to FIGS. 1 to 3, if the RF power 60 is increased, the energy of the plasma 12 may be increased. For example, an ion energy of the plasma 12 may be increased in proportion to the RF power 60.

The plasma 12 may include positive ions that are produced from the reaction gas supplied into the chamber. The positive ions may be distributed in the chamber 10 and on the substrate W. For example, the positive ions may have an angular distribution with respect to a top surface of the substrate W. An ion flux of the plasma 12 may be calculated based on the angular distribution of the positive ions that are incident on the substrate W. An etch rate of the substrate W may be dependent on the ion energy and the ion flux of positive ions that are incident on the substrate W. The etch rate of the substrate W may be proportional to the ion energy and the ion flux and thus, the etch rate of the substrate W may be obtained by multiplying the ion energy by the ion flux. Under control of the RF power controller 46, the valley angle of the valley 70 may change, based on the ion energy and the ion flux of the plasma 12. The change in the valley angle of the valley 70 may be utilized to etch the substrate W at a desired etch rate.

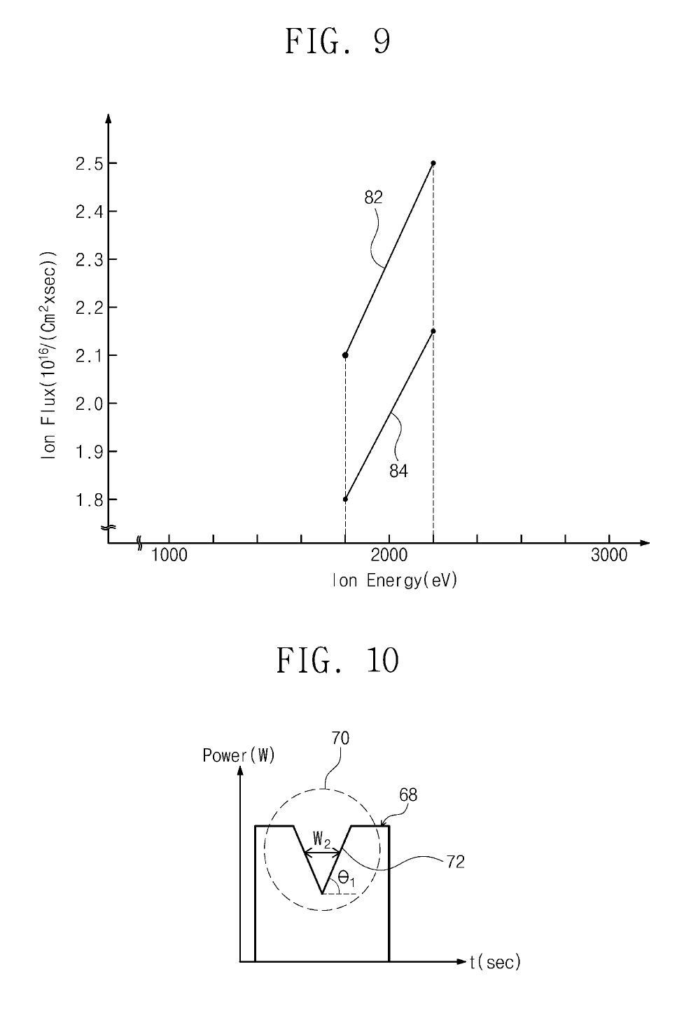

FIG. 9 is a graph showing a change in ion flux caused by a change in ion energy of the plasma 12 of FIG. 1. In FIG. 9, the lines 82 and 84 represent the ion fluxes that are associated with the pulse 68 and the typical pulse 69, respectively. The typical pulse 69 may have a rectangular waveform. As the ion energy of the plasma 12 increases, the angular distribution of the ions that are incident on the wafer W may become more directional so that the ion flux increases. The energy of ions of the plasma incident on the electrode may thus be proportional to the absolute value of the valley angle.

Referring to FIG. 9, a change in the ion flux 82 may be greater than a change in the ion flux 84.

For example, at ion energy of 1800 eV, the ion flux 82 may be about 2.1×10¹⁶/(m²·sec). The ion flux 84 may be about 1.8×10¹⁶/(m²·sec). Multiplication of the ion energy and the ion flux 82 or 84 may correspond to an area of a region between the line 82 or 84 and the x axis in FIG. 9. The etch rate of the substrate W may be dependent on (e.g., proportional to) such an area.

At ion energy of 2200 eV, the ion flux 82 may be about 2.5×10¹⁶/(m²·sec). A change in the etch rate of the substrate W may be proportional to the change in the ion flux 82. The change in the ion flux 82 may be about 0.5×10¹⁶/(m²·sec). The change in the ion flux 84 may be about 0.35×10¹⁶/(m²·sec). The change in the ion flux 84 may be smaller than the change in the ion flux 82. Accordingly, the ion flux 82 may change at a higher rate than that of the ion flux 84.

FIG. 10 illustrates the pulse 68, in which the valley 70 has a second valley width W₂ smaller than the first valley width W₁ of FIG. 3.

Referring to FIGS. 3 and 10, a reduction in valley width of the valley 70 of the pulse 68 may lead to an increase of ion flux of incoming ions onto the wafer W. For example, if a valley width of the valley 70 of the pulse 68 is decreased from the first valley width W₁ to the second valley width W₂, the ion flux may be increased. The valley angle of the oblique lines 72 of the valley 70 may be maintained to the first valley angle θ₁. The second valley width W₂ may be about 1-2 seconds. When the valley 70 has the second valley width W₂, the bottom line 74 of FIG. 3 may vanish. For example, an etch rate of the substrate W may be inversely proportional to a valley width of the valley 70 of the pulse 68. The energy of ions of the plasma incident on the electrode may thus be inversely proportional to the valley width.

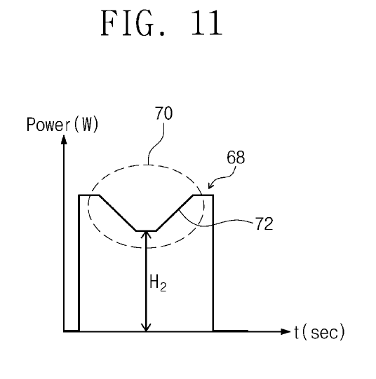

FIG. 11 illustrates the pulse 68, in which the valley 70 has a second height H2 greater than the first height H1 of FIG. 3.

Referring to FIGS. 3 and 11, the higher a height of the bottom line 74 of the valley 70, the higher the ion energy. For example, if a height of the bottom line 74 of the valley 70 is increased from the first height H₁ to the second height H2, the ion energy may be increased.

However, in the case where the second height H₂ is excessively increased, the ion flux may be decreased. A length of the oblique lines 72 may be reduced. If the oblique lines 72 of the valley 70 have a reduced length, a margin for a change in the ion flux 84 may be decreased. An ion flux of the typical pulse 69 with a rectangular waveform may be smaller than an ion flux of the pulse 68 with the valley 70. An increase in the second height H₂ of the valley 70 may lead to an increase in etch rate of the substrate W. Under control of the RF power controller 46 of FIG. 1, the width of the valley 70 may change, based on the ion energy and the ion flux of the plasma 12. The change in the height of the valley 70 may be utilized to etch the substrate W at a desired etch rate.

Hereinafter, a method of fabricating a semiconductor device using the RF power 60, in which the pulse 68 has the valley 70, will be described.

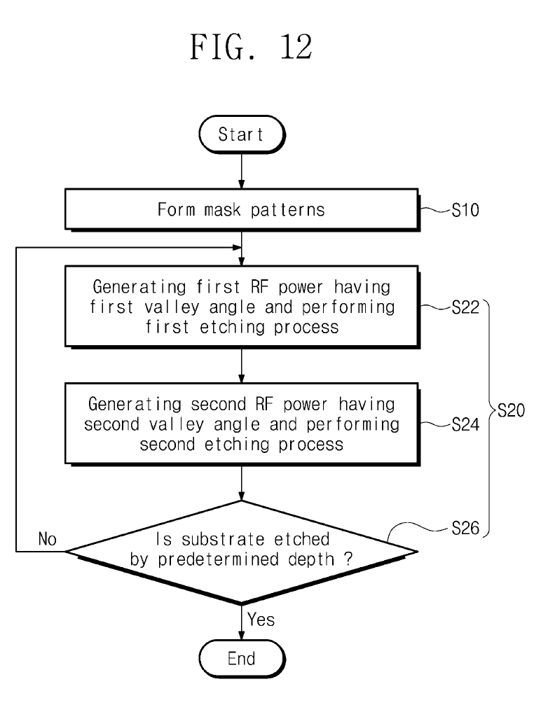

FIG. 12 illustrates an example of a method of fabricating a semiconductor device using the RF power 60 of FIG. 1 according to an exemplary embodiment of the present inventive concept.

Referring to FIG. 12, the fabrication method may include forming the mask pattern 14 (in S10) and etching the substrate W (in S20).

Referring to FIGS. 7 and 12, the mask pattern 14 may be formed on the substrate W (in S10). For example, the mask pattern 14 may be formed by a photolithography process and a mask patterning process.

Referring to FIGS. 1 to 8 and 12, the substrate W may be etched (in S20). For example, the plasma 12 may be used to form the trench 18 in the substrate W. In an exemplary embodiment, the step of etching the substrate W (in S20) may include generating a first RF power and performing a first etching process using the first RF power (in S22), generating a second RF power and performing a second etching process using the second RF power (in S24), and determining whether the substrate W is etched to a predetermined depth (in S26). Here, the first RF power may be generated in such a way that the pulse 68 has the valley 70 of the first valley angle θ₁, and the second RF power may be generated in such a way that the pulse 68 has the valley 70 of the second valley angle θ₂, where the second valley angle θ₂ greater than the first valley angle θ₁.

Under control of the RF power controller 46, the RF power 60, in which the pulse 68 has the valley 70 of the first valley angle θ₁, may be provided to form the polymer 16 on a sidewall of the trench 18 while the first etching process is performed (in S22). The first valley angle θ₁ may be about 45°, for example.

Next, under the control of the RF power controller 46, the RF power 60, in which the pulse 68 has the valley 70 of the second valley angle θ₂, may be provided to remove the polymer 16 from the bottom and sidewall of the trench 18 and etch a portion of the substrate W in the second etching process (in S24). The second valley angle θ₂ may be about 90°. Accordingly, since the bottom of the trench 18 is etched and the sidewall of the trench 18 is protected by the polymer 16, the trench 18 may have an increased etching depth with an increased aspect ratio.

Thereafter, the RF power controller 46 may determine whether the substrate W is etched to a desired depth (in S26). If the substrate W is not etched to the desired depth, the steps S22 to S26 may be repeated under the control of the RF power controller 46.

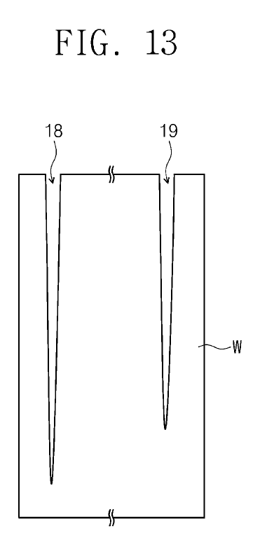

In FIG. 13, the trench 18 may be formed using the pulse 68 of FIG. 2 and a typical trench 19 may be formed using the typical pulse 69.

Referring to FIG. 13, the trench 18 may be formed at a greater depth than the typical trench 19. In the case where the pulse 68 is used to have the valley 70 as shown in FIG. 3, the trench 18 may be formed at a greater depth and/or profile than the typical trench 19. The typical trench 19 is formed by controlling a power of typical pulse 69 in FIG. 2. In an exemplary embodiment, if the pulse 68 with the valley 70 is used, it may be possible to increase etch uniformity or to increase an etching depth (e.g., of the trench 18).

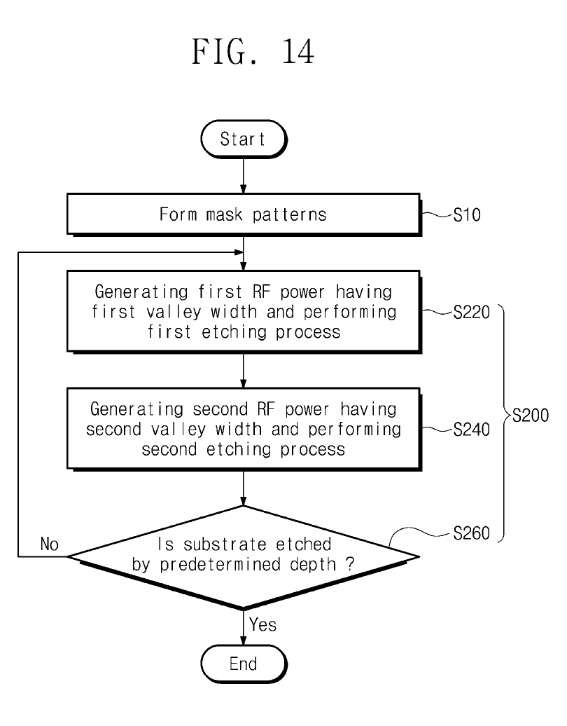

FIG. 14 illustrates an example of a method of fabricating a semiconductor device using the RF power 60 of FIG. 1.

Referring to FIG. 14, a valley width of the pulse 68 may be controlled, when an etching process is performed on the substrate W (in S200). The mask patterns 14 may be formed in the same manner as that of FIG. 12 (in S10).

The etching of the substrate W (in S200) may include generating a first RF power and performing a first etching process using the first RF power (in S220), generating a second RF power and performing a second etching process using the second RF power (in S240), and determining whether the substrate W is etched to a desired depth (in S260). Here, the first RF power may be generated in such a way that the pulse 68 has the valley 70 with a first valley width W₁, and the second RF power may be generated in such a way that the pulse 68 has the valley 70 with a second valley width W₂ greater than the first valley width W₁.

Referring to FIGS. 1 to 8, 11, and 14, under control of the RF power controller 46, the pulse 68 of the RF power 60, in which the valley 70 with a first valley width W₁, may be provided to form the polymer 16 on the sidewall of the trench 18 (in S220).

Next, the pulse 68 of the RF power 60, in which the valley 70 with a second valley width W₂, may be provided to etch the substrate W and the polymer 16 deposited on the sidewall of the trench 18 in S220 through the trench 18 (in S240). Thus, since the bottom of the trench 18 is etched and the sidewall of the trench 18 is protected by the polymer 16, the trench 18 may have both an increased etching depth and an increased aspect ratio.

Thereafter, the RF power controller 46 may determine whether the substrate W is etched to a desired depth (in S260). This step may be performed in the same manner as that of FIG. 12.

With reference to FIGS. 2, 3, 6, 7, 8 and 12, a method of fabricating a semiconductor device by changing the pulse shape of the RF power 60 of FIG. 1 from the pulse shape of FIG. 3 to the pulse shape of FIG. 6.

In step S10, a mask pattern may be formed on a wafer W.

In step S22, a first RF power is generated to have a plurality of first pulses, each of the plurality of first pulses having a first valley-shaped envelope of FIG. 3. A first etching process is performed on the substrate using the first RF power to form a trench 18 having a first depth while a polymer 16 is deposited on a sidewall of the trench 18.

In step S24, a second RF power is generated to have a plurality of second pulses, each of the plurality of second pulses having a second valley-shaped envelop of FIG. 6. A second etching process is performed on the substrate W having the trench 18 and the polymer 16 on the sidewall of the trench 18 using the second RF power so that a bottom of the trench is etched down to a second depth and the polymer 16 on the sidewall of the trench 18 is removed. The first valley-shaped envelope of FIG. 6 is defined by a first valley angle θ₁ and a first valley width W₁. The second valley-shaped envelop of FIG. 6 is defined by a second valley angle θ₂ and a second valley width W₂. The polymer 16 is generated from the substrate W in the first etching process in step S22.

In FIG. 3, each of the plurality of first pulses 68 has a first maximum RF power level Pₘₐₓ, a first minimum RF power level Pₘᵢₙ, and a first intermediate RF power level P_{intermediate}. Each of the plurality of first pulses 68 includes a first rising edge RE extending from the first minimum RF power level Pₘᵢₙ to the first maximum RF power level Pₘₐₓ, a first falling edge FE extending from the first maximum RF power level Pₘₐₓ to the first minimum RF power level Pₘᵢₙ, a first left-valley hill 72-1 extending from the first maximum RF power level Pₘₐₓ to the first intermediate RF power level P_{intermediate} and a first right-valley hill 72-2 extending from the first intermediate RF power level P_{intermediate} to the first maximum RF power level Pₘₐₓ.

In FIG. 6, each of the plurality of second pulses 68 has a second maximum RF power level P′ₘₐₓ, a second minimum RF power level P′ₘᵢₙ, and a second intermediate RF power level P′_{intermediate}. Each of the plurality of second pulses 68 has a second rising edge RE′ extending from the second minimum RF power level P′ₘᵢₙ to the second maximum RF power level P′ₘₐₓ, a second falling edge FE′ extending from the second maximum RF power level P′ₘₐₓ to the second minimum RF power level P′ₘᵢₙ, a second left-valley hill 72′-1 extending from the second maximum RF power level P′ₘₐₓ to the second intermediate RF power level P′_{intermediate} and a second right-valley hill 72′-2 extending from the second intermediate RF power level P′_{intermediate} to the second maximum RF power level P′ₘₐₓ. In an exemplary embodiment, the first maximum RF power level Pₘₐₓ and the second maximum RF power level P′ₘₐₓ may be substantially the same; the first minimum RF power level Pₘᵢₙ and the second minimum RF power level P′ₘᵢₙ may be substantially the same; or the first intermediate RF power level P_{intermediate} and the second intermediate RF power level P′_{intermediate} may be substantially the same.

In FIG. 3, each of the plurality of first pulses 68 further includes a first valley bottom 74 connecting the first left-valley hill 72-1 and the first right-valley hill 72-2 at the first intermediate RF power level P_{intermediate}.

In FIG. 6, each of the plurality of second pulses 68 further includes a second valley bottom 74′ connecting the second left-valley hill 72′-1 and the second right-valley hill 72′-2 at the second intermediate RF power level P′_{intermediate}.

In FIGS. 3 and 6, the first right-valley hill 72-2 is sloped at a first valley angle θ₁, and the second right-valley hill 72′-2 is sloped at a second valley angle θ₂ greater than the first valley angle θ₁.

In FIGS. 3 and 6, the first left-valley hill 72-1 and the first right-valley hill 72-2 are spaced apart from each other at the first valley width W₁, and the second left-valley hill 72′-1 and the second right-valley hill 72′-2 are spaced apart from each other at the second valley width W₂ smaller than the first valley width W₁.

According to an exemplary embodiment of the inventive concept, a plasma system may include an RF power supply unit that is configured to generate an RF power in the form of a pulse with a valley-shaped portion. The RF power supply unit may be configured to control at least one of a valley angle and a valley width, and this may make it possible to control an etch rate of a substrate. The depth of a trench, as well as a specific profile of the trench in the substrate may be obtained as targeted by controlling of the valley angle of the pulse.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A plasma system, comprising:
an electrode; and
an RF power supply unit supplying an RF power to the electrode to generate a plasma on the electrode,
wherein the RF power is provided in a pulse having a valley-shaped portion during an on-pulsing interval of the pulse, and
wherein the valley-shaped portion is defined by a valley angle and a valley width.

2. The plasma system of claim 1,
wherein the RF power supply unit is configured to change an absolute value of the valley angle, and
wherein an energy of ions of the plasma incident on the electrode is proportional to the absolute value of the valley angle.

3. The plasma system of claim 1,
wherein the RF power supply unit is configured to change the valley width, and
wherein the energy of ions of the plasma incident on the electrode is inversely proportional to the valley width.

4. The plasma system of claim 1,
wherein the RF power supply unit is configured to control at least one of the valley angle and the valley width of the RF power to adjust an incoming flux of ions of the plasma that is incident on the electrode.

5. The plasma system of claim 4,
wherein the RF power supply unit is configured to control an intermediate RF energy level of the valley-shaped portion to change the energy of the ions of the plasma.

6. The plasma system of claim 1,
wherein the RF power supply unit is configured to produce the pulse of which an envelope is of a letter ‘M’-like shape.

7. The plasma system of claim 1,
wherein the RF power supply unit is configured to produce the pulse of which an envelope is a letter ‘M’-like shape having a curved hill.

8. The plasma system of claim 1,
wherein the RF power supply unit is configured to produce the pulse of which an envelope is of a letter ‘U’-like shape.

9. The plasma system of claim 1,
wherein, during the on-pulsing interval, the pulse has a single valley-shaped waveform.

10. The plasma system of claim 1, further comprising:
a detector measuring optical characteristics of light emitted from the plasma,
wherein the RF power supply unit comprises:
an RF power generator;
an impedance matching circuit provided between the RF power generator and the electrode; and
a RF power controller provided between and connected to the RF power generator and the detector,
wherein the RF power controller controls the RF power generator so that the RF power has the valley angle and the valley width.

11. A method of fabricating a semiconductor device, comprising:
preparing a substrate;
generating plasma using an RF power provided in a pulse; and
etching the substrate using the plasma,
wherein the pulse has a valley-shaped portion during an on-pulsing interval of the pulse,
wherein the valley-shaped portion is defined by a valley angle and a valley width, and
wherein the generating of the plasma includes controlling at least one of a valley angle and a valley width to control an energy of ions of the plasma incident on the substrate.

12. The method of claim 11,
wherein the etching of the substrate comprises:
forming a trench in the substrate using the RF power having a first valley angle of the pulse, while a polymer layer is deposited in a sidewall of the trench of the substrate;
adjusting the RF power to a second valley angle different from the first valley angle of the pulse; and
etching the polymer layer and a bottom surface of the trench of the substrate using the RF power having the second valley angle.

13. The method of claim 12,
wherein the second valley angle is greater than the first valley angle.

14. The method of claim 11,
wherein the etching of the substrate comprises:
forming a trench in the substrate using the RF power having a first valley width of the pulse while a polymer layer is deposited on a sidewall of the trench of the substrate;
adjusting the RF power to a second valley width different from the first valley width of the pulse; and
etching the polymer layer and a bottom surface of the trench of the substrate using the RF power having the second valley width.

15. The method of claim 14,
wherein the second valley width is smaller than the first valley width.

16. A method of fabricating a semiconductor device, comprising:
preparing a substrate;
generating a first RF power having a plurality of first pulses, each of the plurality of first pulses having a first valley-shaped envelope;
performing a first etching process on the substrate using the first RF power to form a trench having a first depth while a polymer is deposited on a sidewall of the trench;
generating a second RF power having a plurality of second pulses, each of the plurality of second pulses having a second valley-shaped envelop; and
performing a second etching process the substrate using the second RF power so that a bottom of the trench is etched down to a second depth and the polymer on the sidewall of the trench is removed,
wherein the first valley-shaped envelope is defined by a first valley angle and a first valley width,
wherein the second valley-shaped envelop is defined by a second valley angle and a second valley width, and
wherein the polymer is generated from the substrate in the performing of the first etching process.

17. The method of claim 16,
wherein each of the plurality of first pulses has a first maximum RF power level, a first minimum RF power level, and a first intermediate RF power level, and
wherein each of the plurality of first pulses includes a first rising edge extending from the first minimum RF power level to the first maximum RF power level, a first falling edge extending from the first maximum RF power level to the first minimum RF power level, a first left-valley hill extending from the first maximum RF power level to the first intermediate RF power level and a first right-valley hill extending from the first intermediate RF power level to the first maximum RF power level.

18. The method of claim 17,
wherein each of the plurality of second pulses has a second maximum RF power level, a second minimum RF power level, and a second intermediate RF power level, and
wherein each of the plurality of second pulses has a second rising edge extending from the second minimum RF power level to the second maximum RF power level, a second falling edge extending from the second maximum RF power level to the second minimum RF power level, a second left-valley hill extending from the second maximum RF power level to the second intermediate RF power level and a second right-valley hill extending from the second intermediate RF power level to the second maximum RF power level.

19. The method of claim 18,
wherein each of the plurality of first pulses further includes a first valley bottom connecting the first left-valley hill and the first right-valley hill at the first intermediate RF power level.

20. The method of claim 18,
wherein the first right-valley hill is sloped at a first valley angle, and
wherein the second right-valley hill is sloped at a second valley angle greater than the first valley angle.
